(19) United States
(12) Patent Application Publication
(10) Pub. No.: US 2008/0318382 A1
(43) Pub. Date: Dec. 25, 2008

(54) METHODS FOR FABRICATING TUNNELING OXIDE LAYER AND FLASH MEMORY DEVICE

(75) Inventors: Peigang Dai, Shanghai (CN); Xiaopeng Yu, Shanghai (CN); Jing Lin, Shanghai (CN); Hualong Song, Shanghai (CN)

Correspondence Address: SQUIRE, SANDERS & DEMPSEY L.L.P., 1 MARITIME PLAZA, SUITE 300, SAN FRANCISCO, CA, 94111, US

(73) Assignee: Semiconductor Manufacturing International (Shanghai) Corporation, Shanghai (CN)

(21) Appl. No.: 11/956,005

(22) Filed: Dec. 13, 2007

(30) Foreign Application Priority Data
Jun. 21, 2007 (CN) 200710042350.4

(51) Int. Cl. H01L 21/336; H01L 21/283

(52) U.S. Cl. 438/264; 438/770; 257/E21.422; 257/E21.159

(57) ABSTRACT

A method for manufacturing a tunneling oxide layer including the following steps: forming a tunneling oxide layer on a semiconductor substrate by in-situ steam generation oxidation; performing a annealing on the tunneling oxide layer. There is also provided a method for manufacturing a flash memory device. According to the invention, the dangling bonds between silicon oxide in a tunneling oxide layer and silicon adjacent to a semiconductor substrate interface are terminated by performing a annealing on a tunneling oxide layer, thereby improving the erase rate of the tunneling oxide layer.

### FIELD OF THE INVENTION

The present invention generally relates to a process of manufacturing a semiconductor device, and more particularly, to a method for manufacturing a tunneling oxide layer and a method for manufacturing a flash memory device containing the tunneling oxide layer.

### DESCRIPTION OF THE RELATED ART

Flash memory device is a non-volatile memory device, which can still remain the information therein even if the supply power is not supplied, and can be electrically erasable and programmable without needing a special high voltage. Flash memory device has characteristics of low cost and high density. It is widely applied in various applications due to these properties thereof, including an embedded system, such as PC and peripheral equipments, telecom commutators, cell phones, network interconnection equipments, apparatus and instruments, and automobile devices, and also including products for sounds, images, data storage, such as digital camera, digital recorder and PDA (Personal Digital Assistant).

Flash memory device is generally designed to have a Stack-Gate structure, this structure including a tunneling oxide layer, a polysilicon floating gate for storing charges, an inter-gate dielectric layer of Oxide-Nitride-Oxide (ONO) structure, and a polysilicon control gate for controlling the data access.

FIGS. 1 to 4 are cross-sectional views illustrating a conventional process of manufacturing a flash memory device. Reference to FIG. 1, there is provided a semiconductor substrate 100 including an isolation area 102 and an active area 104 disposed between the isolation areas 102; and then a tunneling oxide layer 106 is formed above the semiconductor substrate 100 of the active area 104 is formed, in which the tunneling oxide layer 106 is formed of silicon oxide.

The conventional process for forming the tunneling oxide layer 106 is thermal oxidation method, in which the semiconductor substrate 100 is exposed to the oxygen-containing atmosphere at a high temperature. The process is usually performed in a furnace; and the resulting tunneling oxide layer 106 usually has a thickness of about several ten angstroms.

As shown in FIG. 2, a first conductive layer 108 is formed on the tunneling oxide layer 106. The first conductive layer 108 is for example formed of doped polysilicon. The first conductive layer 108 is formed by the following steps: depositing a polysilicon layer by low-pressure chemical vapor deposition (LPCVD) with silicane as a gas source, then performing a dopant planting process on the polysilicon layer, wherein the temperature and the pressure in above-mentioned deposition process are 575° C.˜650° C. and 0.3 Torr˜0.6 Torr (1 Torr=133.32 Pa) respectively. Next, an inter-gate dielectric layer 116 is formed on the first conductive layer 108. The inter-gate dielectric layer 116 is for example formed of silicon oxide, silicon oxide/silicon nitride or silicon oxide/silicon nitride/silicon oxide (ONO). Flash memory device requires the silicon oxide layer contacting the floating gate to have a good electrical property, in order to prevent leakage or premature electric breakdown arising in the floating gate for storing charges under a normal voltage. As an example, the inter-gate dielectric layer 116 with a structure of silicon oxide/silicon nitride/silicon oxide is formed as follows: forming a uniform silicon oxide layer 110 by low-pressure chemical vapor deposition (LPCVD), then forming a silicon nitride layer 112 on the silicon oxide layer 110 by low-pressure chemical vapor deposition, finally forming another silicon oxide layer 114 by low-pressure chemical vapor deposition.

Then, a second conductive layer 118 is formed on the inter-gate dielectric layer 116 by using chemical vapor deposition, and the second conductive layer 118 is for example formed of doped polysilicon or metal silicide. A top cover layer 120 is formed on the second conductive layer 118 by using chemical vapor deposition, and the top cover layer 120 is formed of silicon nitride.

As shown in FIG. 3, a photoresist layer (not show) is formed on the top con layer 120, and a gate pattern is defined after exposure and development. The top cover layer 120 and the second conductive layer 118 are etched by using the photoresist layer as a mask to form a control gate 118a. The inter-gate dielectric layer 116, the first conductive layer 108, and the tunneling oxide layer 106 are etched by further using the photoresist layer as a mask to form a floating gate 108a; so that the top cover layer 120, the control gate 118a, the inter-gate dielectric layer 116, the floating gate 108a and the tunneling oxide layer 106 constitute a stack-gate structure.

Referring to FIG. 4, the photoresist layer is removed by ashing; and ions are planted into the semiconductor substrates 100 of the active area 104 at both sides of the stack-gate structure by using the stack-gate structure as a mask, to form a source/drain 122. Then, a spacer 124 is formed on both sidewalls of the stack-gate structure. Finally a subsequent wiring process is performed to form a flash memory device.

The Chinese patent application No. 200410033268 also discloses some information about the technical solution as described above. In this application, a tunneling oxide layer is also formed by furnace oxidation method.

In the conventional methods for manufacturing flash memory device, the furnace oxidation method is commonly used to form a tunneling oxide layer. However, since the reaction between oxygen molecule or water molecule and silicon on the surface of the semiconductor substrate in the furnace oxidation method is weak and the semiconductor substrate at the edge of the isolation area presents an arc form, the center portion of the resulting tunneling oxide layer is thicker than the peripheral portion thereof. As shown in FIG. 5, the thickness H of the center portion of the resulting tunneling oxide layer measured by a transmission electron microscope(TEM) is 104 angstroms, while the thickness H′ of the peripheral portion is 73 angstroms, i.e., the thickness difference between them is 31 angstroms. This thickness difference will cause the peripheral portion to be broken down easily when a subsequent voltage is applied on it.

To resolving the above-mentioned problems, an in-situ steam generation (ISSG) oxidation is employed. Since the reaction between oxygen atom and silicon on the surface of the semiconductor substrate is strong, the resulting tunneling oxide layer is compacted and has a good capacity for shape keeping, and the thickness of the center portion of the tunneling oxide layer is substantially close to that of the peripheral portion thereof. The difference between the thicknesses of the center portion and the peripheral portion of the resulting tunneling oxide layer formed by in-situ steam generation oxidation is in a range of 0 angstrom ˜5 angstroms when measured by transmission electron microscope, as shown in FIG. 6. The thickness L of the center portion of the resulting tunneling oxide layer is 97 angstroms, and the thickness L′ of the peripheral portion is 94 angstroms, so that the difference between L and L′ is 3 angstroms.

However, although the tunneling oxide layer formed by in-situ steam generation oxidation has good capacity for shape keeping, there are many dangling bonds in the interface between silicon in semiconductor substrate and silicon oxide in the tunneling oxide layer, and thus an interface trap is produced. When a voltage is applied to the semiconductor substrate to erase the charges in the floating gate, the charges can be trapped by the interface trap during passing through the interface between silicon in semiconductor substrate and silicon oxide in the tunneling oxide layer, thereby, the charges can not be erased fluently. Therefore the erase rate of the tunneling oxide layer formed by in-situ steam generation oxidation is slower.

### SUMMARY OF THE INVENTION

The present invention provides a method for manufacturing a tunneling oxide layer and a method for manufacturing a flash memory device to prevent the slow erase rate of the tunneling oxide layer.

In an aspect according to the present invention, there is provided a method for manufacturing a tunneling oxide layer comprising the following steps: forming a tunneling oxide layer on a semiconductor substrate by in-situ steam generation oxidation; and performing an annealing on the tunneling oxide layer.

Preferably, the in-situ steam generation oxidation is performed at a pressure in a range of 3 Torr˜15 Torr and a temperature in a range of 900° C.˜1100° C. for 10 seconds˜100 seconds. The gas used in the in-situ steam generation oxidation is hydrogen (H₂) and oxygen (O₂). The ratio of H₂ to O₂ is 3/10˜1/1. The flow rate of H₂ is 3 SLM˜20 SLM and the flow rate of O₂ is 3 SLM˜20 SLM.

Preferably, the annealing is a furnace annealing. The annealing is performed at a temperature in a range of 900° C.˜1100° C. for 10 minutes˜200 minutes. The gas used in the annealing is nitrogen (N₂). The flow rate of N₂ is 3 SLM˜20 SLM.

Preferably, the thickness of the tunneling oxide layer is in a range of 30 angstroms˜150 angstroms.

In another aspect according to the present invention, there is provided a method for manufacturing a flash memory device comprising the following steps: forming a tunneling oxide layer on a semiconductor substrate by in-situ steam generation oxidation; performing an annealing on the tunneling oxide layer; forming a control gate and a floating gate sequentially on the annealed tunneling oxide layer; forming a source/drain in the semiconductor substrate at both sides of the gate; and performing a wiring process to form a flash memory device.

Preferably, the step of forming the control gate and the floating gate further comprises: forming a first conductive layer, an inter-gate dielectric layer, a second conductive layer and a top cover layer sequentially on the annealed tunneling oxide layer; forming a patterned photoresist layer on the top cover layer to define a gate; etching the top cover layer, the second conductive layer, the inter-gate dielectric layer, the first conductive layer and the tunneling oxide layer by using the photoresist layer as a mask to form a control gate and a floating gate.

In yet another aspect according to the present invention, there is provided a method for manufacturing a tunneling oxide layer comprising the following steps: forming a tunneling oxide layer on a semiconductor substrate by in-situ steam generation oxidation; forming a control gate and a floating gate sequentially on the tunneling oxide layer; and then performing an annealing on the tunneling oxide layer.

Preferably, the in-situ steam generation oxidation is performed at a pressure in a range of 3 Torr˜15 Torr and a temperature in a range of 900° C.˜1100° C. for 10 seconds˜100 seconds. The gas used in the in-situ steam generation oxidation is hydrogen (H₂) and oxygen (O₂). The ratio of H₂ to O₂ is 3/10˜1/1. The flow rate of H₂ is 3 SLM˜20 SLM and the flow rate of O₂ is 3 SLM˜20 SLM.

Preferably, the annealing is a furnace annealing. The annealing is performed at a temperature in a range of 900° C.˜1100° C. for 10 minutes˜200 minutes. The gas used in the annealing is nitrogen (N₂). The flow rate of N₂ is 3 SLM˜20 SLM.

Preferably, the thickness of the tunneling oxide layer is in a range of 30 angstroms˜150 angstroms.

Preferably, the step of forming the control gate and the floating gate further comprises: forming a first conductive layer, an inter-gate dielectric layer, a second conductive layer and a top cover layer sequentially on the tunneling oxide layer; forming a patterned photoresist layer on the top cover layer to define a gate; and etching the top cover layer, the second conductive layer, the inter-gate dielectric layer, the first conductive layer and the tunneling oxide layer by using the photoresist layer as a mask to form a control gate and a floating gate.

In still another aspect according to the present invention, there is provided a method for manufacturing a flash memory device comprising the following steps: forming a tunneling oxide layer on a semiconductor substrate by in-situ steam generation oxidation; forming a control gate and a floating gate sequentially on the tunneling oxide layer; then performing an annealing on the tunneling oxide layer; forming a source/drain in the semiconductor substrate at both sides of the gate; and performing a wiring process to form a flash memory device.

Preferably, the step of forming the control gate and the floating gate further comprises: forming a first conductive layer, an inter-gate dielectric layer, a second conductive layer and a top cover layer sequentially on the tunneling oxide layer; forming a patterned photoresist layer on the top cover layer to define a gate; etching the top cover layer, the second conductive layer, the inter-gate dielectric layer, the first conductive layer and the tunneling oxide layer by using the photoresist layer as a mask to form a control gate and a floating gate.

Compared with the prior art, the present invention has the following advantages: forming a tunneling oxide layer on a semiconductor substrate by in-situ steam generation oxidation; then performing an annealing on the tunneling oxide layer before or after forming a control gate and a floating gate sequentially on the annealed tunneling oxide layer, so that the dangling bonds between silicon oxide in the tunneling oxide layer and silicon adjacent to a semiconductor substrate interface are terminated, thereby improving the erase rate of the tunneling oxide layer.

### BRIEF DESCRIPTION OF THE DRAWINGS

FIG. 1 to FIG. 4 are schematic views showing a conventional method for manufacturing a flash memory device;

FIG. 5 is a transmission electron microscope image of the tunneling oxide layer formed by using the conventional furnace thermal oxidation;

FIG. 6 is a transmission electron microscope image of the tunneling oxide layer formed by using the conventional in-situ steam generation oxidation;

FIG. 7 is a flow chart showing a method for manufacturing a tunneling oxide layer according to a first embodiment of the invention;

FIG. 8 is a flow chart showing a method for manufacturing a flash memory device according to a first embodiment of the invention;

FIG. 9 to FIG. 14 are schematic views showing a method for manufacturing a flash memory device according to a first embodiment of the invention;

FIG. 15 is a flow chart showing a method for manufacturing a tunneling oxide layer according to a second embodiment of the invention;

FIG. 16 is a flow chart showing a method for manufacturing a flash memory device according to a second embodiment of the invention;

FIG. 17 to FIG. 22 are schematic views showing a method for manufacturing a flash memory device according to a second embodiment of the invention.

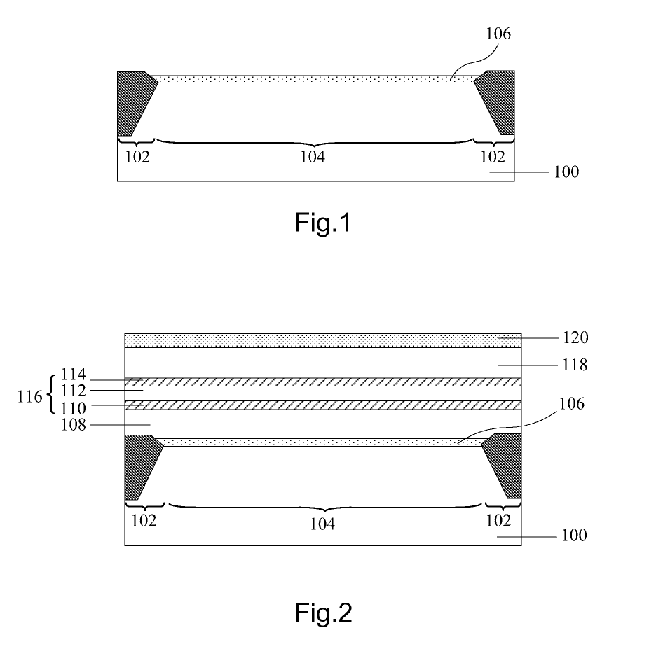

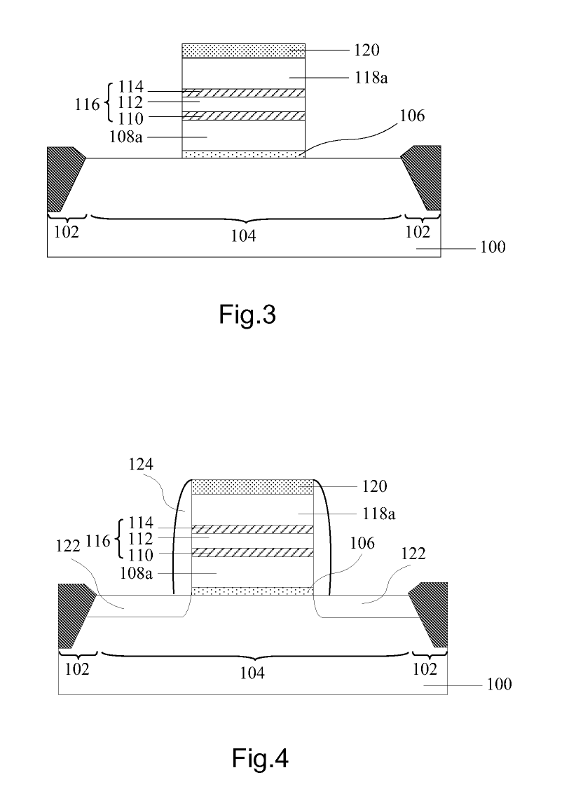

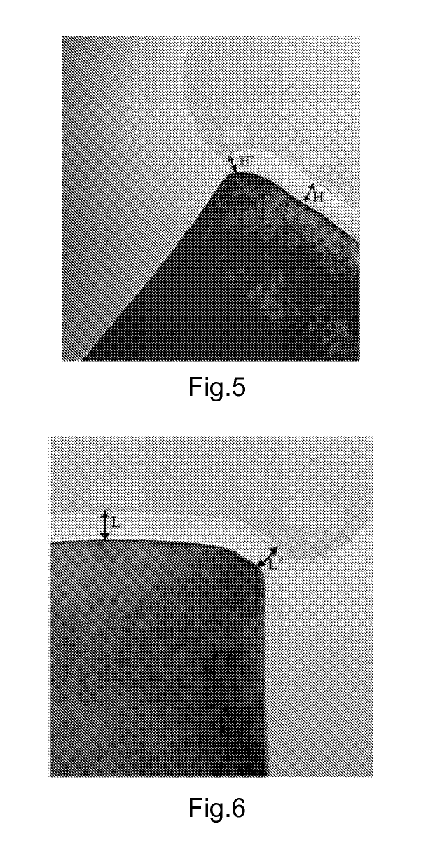

### SPECIFIC EMBODIMENTS OF THE INVENTION

According to the present invention, a tunneling oxide layer is formed on a semiconductor substrate by in-situ steam generation oxidation; then an annealing is performed on the tunneling oxide layer before or after forming a control gate and a floating gate sequentially on the annealed tunneling oxide layer, so that the dangling bonds between silicon oxide in the tunneling oxide layer and silicon adjacent to a semiconductor substrate interface are terminated, thereby improving the erase rate of the tunneling oxide layer.

Hereinafter, embodiments of the present invention will be described in detail with reference to the attached drawings.

### First Embodiment

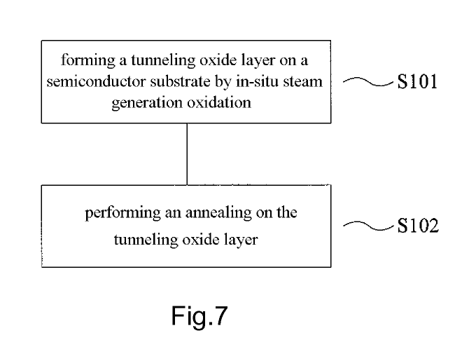

FIG. 7 is a flow chart showing a method for manufacturing a tunneling oxide layer according to the first embodiment of the invention. As shown in FIG. 7, in step S101, a tunneling oxide layer is formed on a semiconductor substrate by in-situ steam generation oxidation. In step S102, an annealing is performed on the tunneling oxide layer.

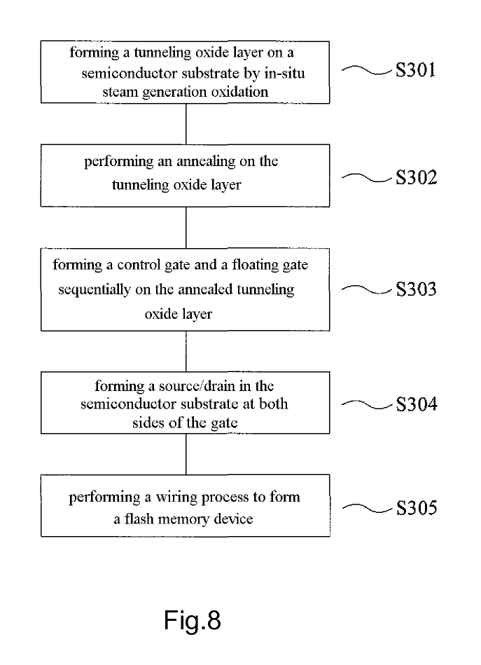

FIG. 8 is a flow chart showing a method for manufacturing a flash memory device according to the first embodiment of the invention. As shown in FIG. 8, in step S301, a tunneling oxide layer is formed on a semiconductor substrate by in-situ steam generation oxidation. In step S302, an annealing is performed on the tunneling oxide layer. In step S303, a control gate and a floating gate are formed sequentially on the annealed tunneling oxide layer. In step S304, a source/drain is formed in the semiconductor substrate at both sides of the gate. In step S305, a wiring process is performed to form a flash memory device.

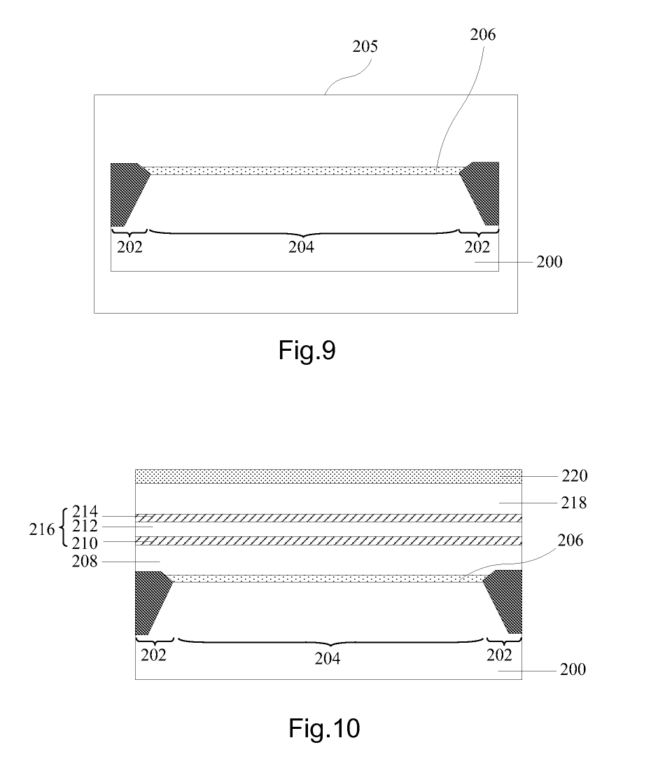

FIG. 9 to FIG. 14 are graphical illustrations showing a method for manufacturing a flash memory device according to the first embodiment of the invention. As shown in FIG. 9, there is provided a semiconductor substrate 200 including an isolation area 202 and located in an active area 204 between the isolation areas 202. Then, a tunneling oxide layer 206 is formed above the semiconductor substrate 200 of the active area 204 by using in-situ steam generation oxidation. The semiconductor substrates 200 with the tunneling oxide layer 206 is placed into a furnace 205 to perform an annealing on the tunneling oxide layer 206 so that the dangling bonds between silicon oxide in the tunneling oxide layer 206 and silicon adjacent to the semiconductor substrate 200 interface are terminated.

In this embodiment, the in-situ steam generation oxidation is performed at a pressure in a range of 3 Torr˜15 Torr, such as 3 Torr, 5 Torr, 8 Torr, 10 Torr, 12 Torr or 15 Torr etc., and a temperature in a range of 900° C.˜1100° C., such as 900° C., 950° C., 1000° C., 1050° C. or 1100° C. etc., for 10 seconds˜100 seconds, such as 10, 20, 30, 40, 50, 60, 70, 80, 90 or 100 seconds etc.

The gas used in the in-situ steam generation oxidation is hydrogen (H₂) and oxygen (O₂). The ratio of H₂ to O₂ is 3/10˜10/10, such as H₂:O₂=3:10, H₂:O₂=4:10, H₂:O₂=5:10, H₂:O₂=6:10, H₂:O₂=7:10, H₂:O₂=8:10, H₂:O₂=9:10 or H₂:O₂=10:10 etc. The flow rate of H₂ is 3 SLM˜20 SLM, such as 3 SLM, 5 SLM, 10 SLM, 15 SLM or 20 SLM etc. The flow rate of O₂ is 3 SLM˜20 SLM, such as 3 SLM, 5 SLM, 10 SLM, 15 SLM or 20 SLM etc.

In this embodiment, the annealing is performed on the tunneling oxide layer 206 at a temperature in a range of 900° C.˜1100° C., such as 900° C., 950° C., 1000° C., 1050° C. or 1100° C. etc., for 10 minutes˜200 minutes, such as 10 minutes, 20 minutes, 40 minutes, 60 minutes, 80 minutes, 100 minutes, 120 minutes, 140 minutes, 160 minutes, 180 minutes or 200 minutes etc. The gas used in the annealing is nitrogen (N₂). The flow rate of N₂ is 3 SLM˜20 SLM, such as 3 SLM, 4 SLM, 5 SLM, 6 SLM, 7 SLM, 8 SLM, 9 SLM, 10 SLM, 11 SLM, 12 SLM, 13 SLM, 14 SLM, 15 SLM, 16 SLM, 17 SLM, 18 SLM, 19 SLM or 20 SLM etc.

In this embodiment, the thickness of the tunneling oxide layer 206 is in a range of 30 angstroms˜150 angstroms, such as 30 angstroms, 50 angstroms, 70 angstroms, 90 angstroms, 100 angstroms, 110 angstroms, 130 angstroms or 150 angstrom etc.

As shown in FIG. 10, the semiconductor substrates 200 with the tunneling oxide layer 206 is removed from the furnace 205; then a first conductive layer 208 for example formed of doped polysilicon is formed on the tunneling oxide layer 206. The first conductive layer 208 can be formed by the following steps: forming an undoped polysilicon layer by chemical vapor deposition, and then performing a ions doping process. Next, a inter-gate dielectric layer 216 is formed on the first conductive layer 208, for example, by low-pressure chemical vapor deposition, wherein the inter-gate dielectric layer 216 is for example formed of silicon oxide, silicon oxide/silicon nitride or silicon oxide/silicon nitride/silicon oxide (ONO), etc. A second conductive layer 218 is formed on the inter-gate dielectric layer 216 by using chemical vapor deposition, wherein the second conductive layer 218 is for example formed of doped polysilicon or metal silicide. A top cover layer 220 is formed on the second conductive layer 218 by using chemical vapor deposition, wherein the material of the top cover layer 220 has an etch selectivity different from that of a subsequently formed inner dielectric layer, such as silicon nitride.

In this embodiment, the thickness of the first conductive layer 208 is in a range of 500 angstroms˜1500 angstroms, such as 500 angstroms, 600 angstroms, 700 angstroms, 800 angstroms, 900 angstroms, 1000 angstroms, 1100 angstroms, 1200 angstroms, 1300 angstroms, 1400 angstroms or 1500 angstrom etc.

In this embodiment, the integrate dielectric layer 216 is formed of silicon oxide/silicon nitride/silicon oxide, wherein the thickness of the first silicon oxide 210 is in a range of 50 angstroms˜70 angstroms, such as 50 angstroms, 60 angstroms or 70 angstrom etc., preferably 60 angstroms. The thickness of the silicon nitride 212 is in a range of 60 angstroms˜80 angstroms, such as 60 angstroms, 70 angstroms or 80 angstrom etc., preferably 70 angstroms. The thickness of the second silicon oxide 214 is in a range of 50 angstroms˜70 angstroms, such as 50 angstroms, 60 angstroms or 70 angstrom etc., preferably 60 angstroms.

The thickness of the second conductive layer 218 is in a range of 1500 angstroms˜2500 angstroms, such as 1500 angstroms, 1600 angstroms, 1800 angstroms, 2000 angstroms, 2200 angstroms, 2400 angstroms or 2500 angstrom etc.

In this embodiment, the thickness of the top cover layer 220 is in a range of 1000 angstroms˜2000 angstroms, such as 1000 angstroms, 1200 angstroms, 1400 angstroms, 1500 angstroms, 1600 angstroms, 1800 angstroms or 2000 angstrom etc.

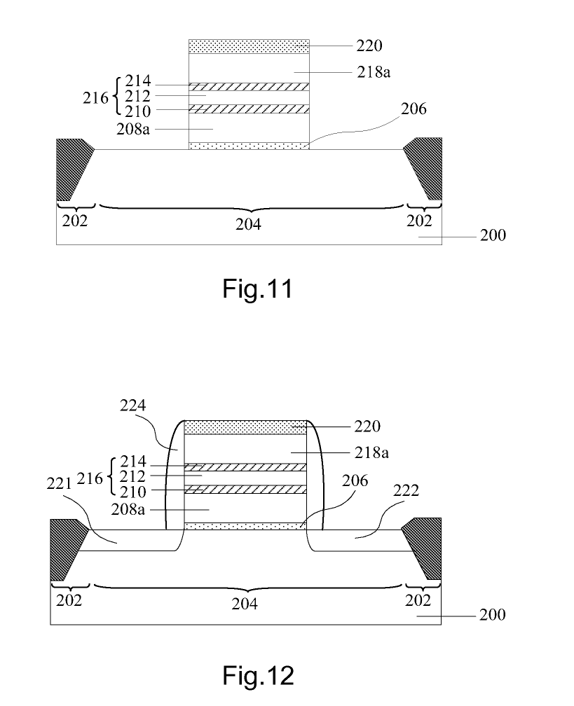

Referring to FIG. 11, a first photoresist layer (not show) is formed on the top cover layer 220 by spin coating, and a gate pattern is defined after exposure and development. The top cover layer 220 and the second conductive layer 218 are etched by using the first photoresist layer as a mask, wherein the etched second conductive layer 218 is used as a control gate 218a. The inter-gate dielectric layer 216, the first conductive layer 208, and the tunneling oxide layer 206 are etched by further using the photoresist layer as a mask until the substrate is exposed, wherein the etched first conductive layer 208 is used as a floating gate 208a. Thereby, the top cover layer 220, the control gate 218a, the inter-gate dielectric layer 216, the floating gate 208a and the tunneling oxide layer 206 constitute a stack-gate structure.

Referring to FIG. 12, the first photoresist layer is removed by ashing. Ions are planted into the semiconductor substrates 200 of the active area 204 at both sides of the stack-gate structure by using the stack-gate structure as a mask, and an annealing process is performed to form a source 221/drain 222. Then, a spacer 224 is formed on both sidewalls of the stack-gate structure. For example, the spacer 224 can be formed by the following steps: firstly forming a insulation layer (not shown), the material of which has an etch selectivity different from that of a subsequently formed inner dielectric layer, such as silicon nitride, and then partially removing the insulation layer by anisotropic etching to form the spacer 224 on each sidewall of the stack-gate structure.

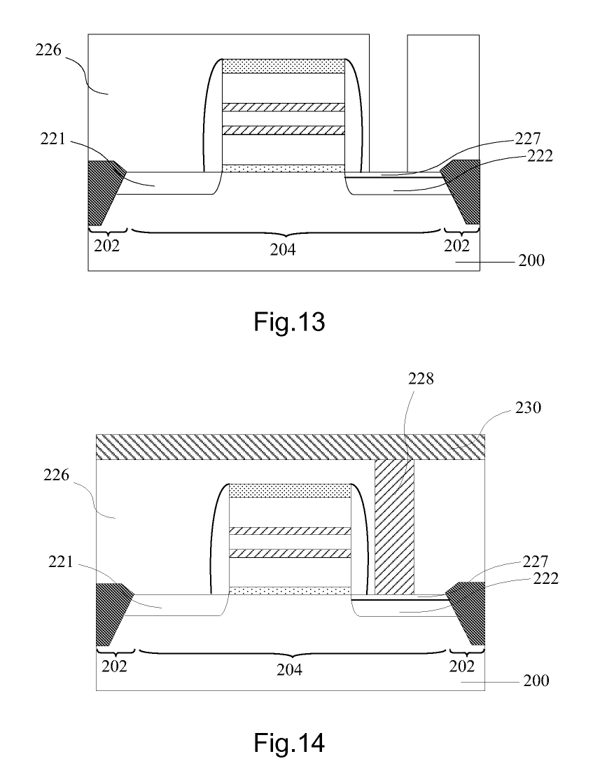

As shown in FIG. 13, a interlayer dielectric layer 226 is formed on the semiconductor substrate 200 and the stack-gate structure by chemical vapor deposition, wherein the interlayer dielectric layer 226 can be formed of boron-phosphorosilicate glass (BPSG) or phosphorosilicate glass (PSG) etc. A second photoresist layer (not show) is formed on the interlayer dielectric layer 226 by spin coating, after exposure and development, a contact hole pattern which corresponds to the drain 222 being defined. The interlayer dielectric layer 226 is etched by using the second photoresist layer as a mask until the drain 222 is exposed, thereby forming a contact hole. The second photoresist layer is removed by ashing. Ions are planted into the substrate 200 along the contact hole to form a doped area 227.

As shown in FIG. 14, a conductive metal layer 228 is formed on the interlayer dielectric layer 226 and within the contact hole by chemical vapor deposition. In this example, the conductive metal layer 228 can be formed of tungsten. Then, the conductive metal layer is planarized by chemical mechanical polishing until the interlayer dielectric layer 226 is exposed, thereby forming a metal plug. Then, a conductor layer 230 connecting to the metal plug electrically is formed on the metal plug and the interlayer dielectric layer 226. The conductor layer 230 can be formed by the following steps: forming a conductive layer (not shown) on the metal plug and the interlayer dielectric layer 226, then performing a lithography process on the conductive layer to form a strip-shaped conductor layer 230.

### Second Embodiment

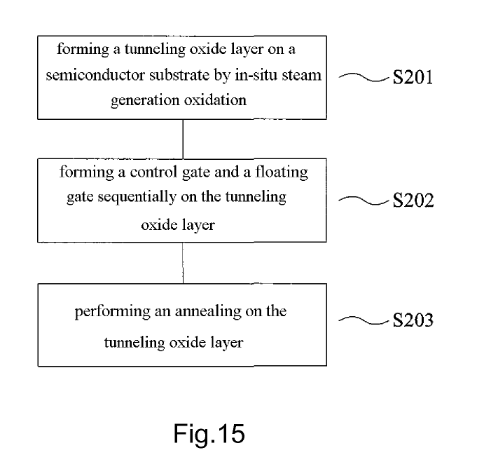

FIG. 15 is a flow chart showing a method for manufacturing a tunneling oxide layer according to the second embodiment of the invention. As shown in FIG. 15, in step S201, a tunneling oxide layer is formed on a semiconductor substrate by in-situ steam generation oxidation. In step S202, a control gate and a floating gate are formed sequentially on the tunneling oxide layer. In step S203, an annealing is performed on the tunneling oxide layer after forming the control gate and the floating gate.

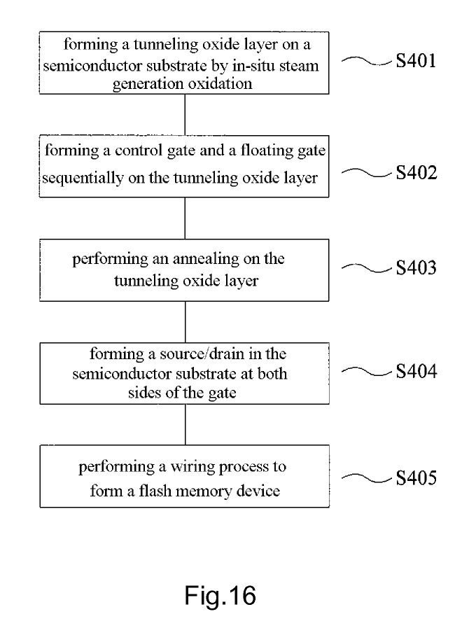

FIG. 16 is a flow chart showing a method for manufacturing a flash memory device according to the second embodiment of the invention. As shown in FIG. 16, in step S401, a tunneling oxide layer is formed on a semiconductor substrate by in-situ steam generation oxidation. In step S402, a control gate and a floating gate are formed sequentially on the tunneling oxide layer. In step S403, an annealing is performed on the tunneling oxide layer after forming the control gate and the floating gate. In step S404, a source/drain is formed in the semiconductor substrate at both sides of the gate. In step S505, a wiring process is performed to form a flash memory device.

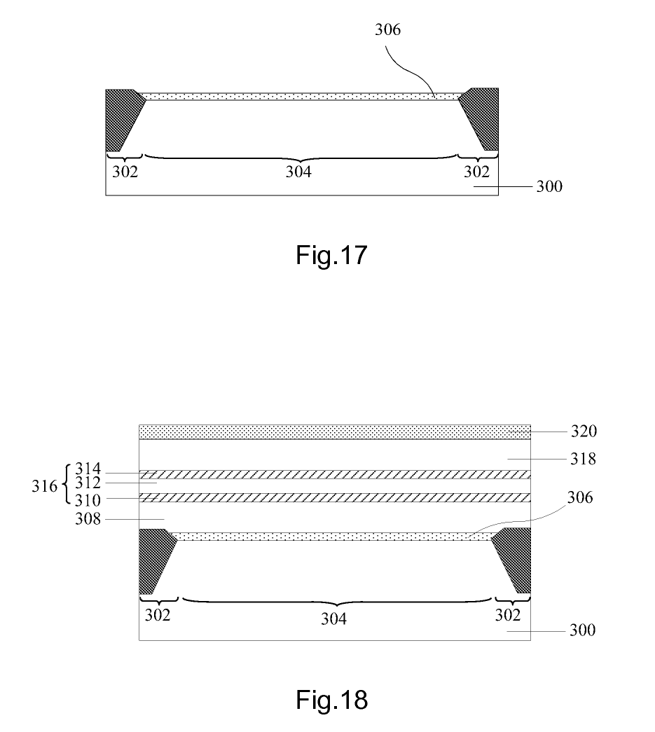

FIG. 17 to FIG. 22 are graphical illustrations showing a method for manufacturing a flash memory device according to the second embodiment of the invention. As shown in FIG. 17, there is provided a semiconductor substrate 300 including an isolation area 302 and an active area 304 between the isolation areas 302. Then, a tunneling oxide layer 306 is formed above the semiconductor substrate 300 of the active area 304 is formed by using in-situ steam generation oxidation.

In this embodiment, the in-situ steam generation oxidation is performed at a pressure in a range of 3 Torr˜15 Torr, such as 3 Torr, 4 Torr, 5 Torr, 6 Torr, 7 Torr, 8 Torr, 9 Torr, 10 Torr, 11 Torr, 12 Torr, 13 Torr, 14 Torr or 15 Torr etc., and a temperature in a range of 900° C.˜1100° C., such as 900° C., 950° C., 1000° C., 1050° C. or 1100° C. etc., for 10 seconds˜100 seconds, such as 10, 20, 30, 40, 50, 60, 70, 80, 90 or 100 seconds etc.

The gas used in the in-situ steam generation oxidation is hydrogen (H₂) and oxygen (O₂). The ratio of H₂ to O₂ is 3/10˜10/10, such as H₂:O₂=3:10, H₂:O₂=4:10, H₂:O₂=5:10, H₂:O₂=6.10, H₂:O₂=7:10, H₂:O₂=8:10, H₂:O₂=9:10 or H₂:O₂=10:10 etc. The flow rate of H₂ is 3 SLM˜20 SLM, such as 3 SLM, 5 SLM, 10 SLM, 15 SLM or 20 SLM etc. The flow rate of O₂ is 3 SLM˜20 SLM, such as 3 SLM, 5 SLM, 10 SLM, 15 SLM or 20 SLM etc.

In this embodiment, the thickness of the tunneling oxide layer 306 is in range of 30 angstroms˜150 angstroms, such as 30 angstroms, 50 angstroms, 70 angstroms, 90 angstroms, 100 angstroms, 110 angstroms, 130 angstroms or 150 angstrom etc.

As shown in FIG. 18, a first conductive layer 308 is formed on the tunneling oxide layer 306, and the first conductive layer 308 is for example formed of doped polysilicon. The first conductive layer 308 can be formed by the following steps: forming an undoped polysilicon layer by chemical vapor deposition, and then performing an ions doping process. Next, an inter-gate dielectric layer 316 is formed on the first conductive layer 308, for example, by low-pressure chemical vapor deposition, wherein the inter-gate dielectric layer 316 is for example formed of silicon oxide, silicon oxide/silicon nitride or silicon oxide/silicon nitride/silicon oxide (ONO), etc. A second conductive layer 318 is formed on the inter-gate dielectric layer 316 by using chemical vapor deposition, wherein the second conductive layer 318 is for example formed of doped polysilicon or metal silicide. A top cover layer 320 is formed on the second conductive layer 318 by using chemical vapor deposition, and the material of the top cover layer 320 has an etch selectivity different from that of a subsequently formed inner dielectric layer, such as silicon nitride.

In this embodiment, the thickness of the first conductive layer 308 is in a range of 500 angstroms˜1500 angstroms, such as 500 angstroms, 600 angstroms, 700 angstroms, 800 angstroms, 900 angstroms, 1000 angstroms, 1100 angstroms, 1200 angstroms, 1300 angstroms, 1400 angstroms or 1500 angstrom etc.

In this embodiment, the integrate dielectric layer 316 is formed of silicon oxide/silicon nitride/silicon oxide, wherein the thickness of the first silicon oxide 310 is in a range of 50 angstroms˜70 angstroms, such as 50 angstroms, 60 angstroms or 70 angstrom etc., preferably 60 angstroms; the thickness of the silicon nitride 312 is in a range of 60 angstroms˜80 angstroms, such as 60 angstroms, 70 angstroms or 80 angstrom etc., preferably 70 angstroms; the thickness of the second silicon oxide 314 is in a range of 50 angstroms˜70 angstroms, such as 50 angstroms, 60 angstroms or 70 angstrom etc., preferably 60 angstroms.

The thickness of the second conductive layer 318 is in a range of 1500 angstroms˜2500 angstroms, such as 1500 angstroms, 1600 angstroms, 1800 angstroms, 2000 angstroms, 2200 angstroms, 2400 angstroms or 2500 angstrom etc.

In this embodiment, the thickness of the top cover layer 320 is in a range of 1000 angstroms˜2000 angstroms, such as 1000 angstroms, 1200 angstroms, 1400 angstroms, 1500 angstroms, 1600 angstroms, 1800 angstroms or 2000 angstrom etc.

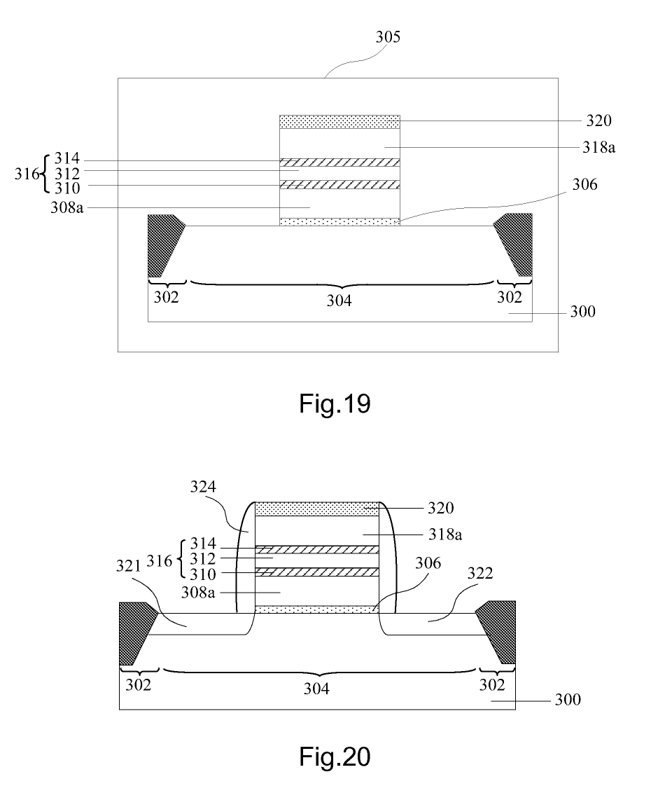

Referring to FIG. 19, a first photoresist layer (not show) is formed on the top cover layer 320 by spin coating, to define a gate pattern after exposure and development. The top cover layer 320 and the second conductive layer 318 are etched by using the first photoresist layer as a mask, and the etched second conductive layer 318 is used as a control gate 318a. The inter-gate dielectric layer 316, the first conductive layer 308, and the tunneling oxide layer 306 are etched by further using the photoresist layer as a mask until the substrate is exposed, and the etched first conductive layer 308 is used as a floating gate 308a. The top cover layer 320, the control gate 318a, the inter-gate dielectric layer 316, the floating gate 308a and the tunneling oxide layer 306 constitute a stack-gate structure. The first photoresist layer is removed by ashing. Then the semiconductor substrates 300 with the above-mentioned layers is placed into a furnace 305, and an annealing is performed on the tunneling oxide layer 306 to terminate the dangling bonds between silicon oxide in the tunneling oxide layer 306 and silicon adjacent to the semiconductor substrate 300 interface.

In this embodiment, the annealing is performed on the tunneling oxide layer 306 at a temperature in a range of 900° C.˜1100° C., such as 900° C., 950° C., 1000° C., 1050° C. or 1100° C. etc., for 10 minutes˜200 minutes, such as 10 minutes, 20 minutes, 40 minutes, 60 minutes, 80 minutes, 100 minutes, 120 minutes, 140 minutes, 160 minutes, 180 minutes or 200 minutes etc. The gas used in the annealing is nitrogen (N₂). The flow rate of N₂ is 3 SLM˜20 SLM, such as 3 SLM, 4 SLM, 5 SLM, 6 SLM, 7 SLM, 8 SLM, 9 SLM, 10 SLM, 11 SLM, 12 SLM, 13 SLM, 14 SLM, 15 SLM, 16 SLM, 17 SLM, 18 SLM, 19 SLM or 20 SLM etc.

Next, referring to FIG. 20, the semiconductor substrates 300 with the above-mentioned layers is removed from the furnace. Then, ions are planted into the semiconductor substrates 300 of the active area 304 at both sides of the stack-gate structure by using the stack-gate structure as a mask, and an annealing process is performed to form a source 321/drain 322. Then, a spacer 324 is formed on both sidewalls of the stack-gate structure, wherein the spacer 324 can be formed for example by the following steps: firstly forming a insulation layer (not shown), the material of which having an etch selectivity different from that of a subsequently formed inner dielectric layer, such as silicon nitride, then partially removing the insulation layer by anisotropic etching to form the spacer 324 on each sidewall of the stack-gate structure.

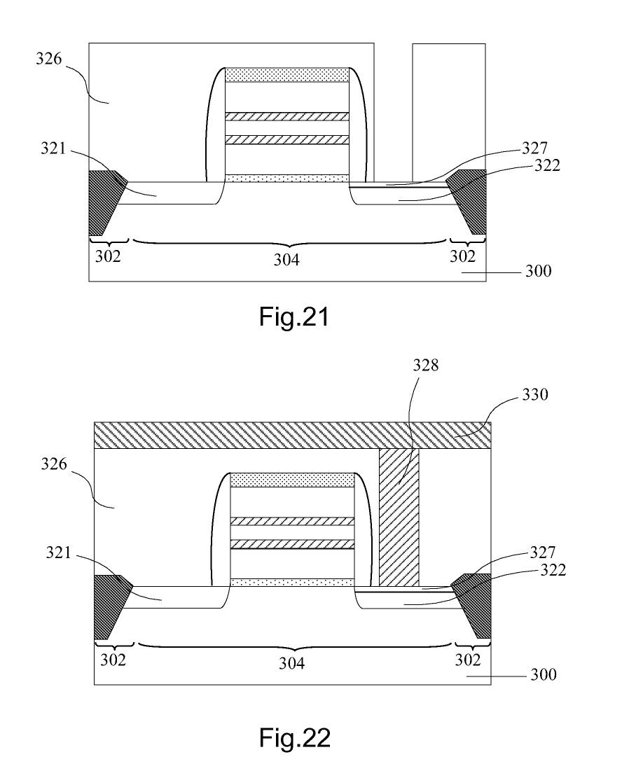

As shown in FIG. 21, a interlayer dielectric layer 326 is formed on the semiconductor substrate 300 and the stack-gate structure by chemical vapor deposition, and the interlayer dielectric layer 326 can be formed of boron-phosphorosilicate glass(BPSG) or phosphorosilicate glass(PSG) etc. A second photoresist layer (not show) is formed on the interlayer dielectric layer 326 by spin coating, after exposure and development, to define a contact hole pattern which corresponds to the drain 322. The interlayer dielectric layer 326 is etched by using the second photoresist layer as a mask until the drain 322 is exposed, thereby forming a contact hole. The second photoresist layer is removed by ashing. Ions are planted into the substrate 300 along the contact hole to form a doped area 327.

As shown in FIG. 22, a conductive metal layer 328 is formed on the interlayer dielectric layer 326 and within the contact hole by chemical vapor deposition. In this case, the conductive metal layer 328 can be formed of tungsten. Then, the conductive metal layer is planarized by chemical mechanical polishing until the interlayer dielectric layer 326 is exposed, thereby forming a metal plug. Next, a conductor layer 330 connecting to the metal plug electrically is formed on the metal plug and the interlayer dielectric layer 326, wherein the conductor layer 330 can be formed by the following steps: forming a conductive layer (not shown) on the metal plug and the interlayer dielectric layer 326, then performing a lithography process on the conductive layer to form a strip-shaped conductor layer 330.

While the present invention has been described with respect to certain preferred embodiments, it will be apparent to those skilled in the art that various changes and modifications may be made without departing from the spirit and scope of the invention as defined in the following claims.

1. A method for manufacturing a tunneling oxide layer, the method comprising the following steps:
forming a tunneling oxide layer on a semiconductor substrate by in-situ steam generation oxidation; and
performing an annealing on the tunneling oxide layer.

2. The method according to claim 1, further comprising performing the in-situ steam generation oxidation at a pressure in a range of 3 Torr˜15 Torr and a temperature in a range of 900° C.˜1100° C. for 10 seconds˜100 seconds.

3. The method according to claim 2, wherein the gas used in the in-situ steam generation oxidation is H₂ and O₂.

4. The method according to claim 3, wherein the ratio of H₂ to O₂ is 3/10˜1/1.

5. The method according to claim 4, wherein the flow rate of H₂ is 3 SLM˜20 SLM, and the flow rate of O₂ is 3 SLM˜20 SLM.

6. The method according to claim 1, wherein the annealing is a furnace annealing.

7. The method according to claim 6, further comprising performing the annealing at a temperature in a range of 900° C.˜1100° C. for 10 minutes˜200 minutes.

8. The method according to claim 7, wherein the gas used in the annealing is N₂.

9. The method according to claim 8, wherein the flow rate of N₂ is 3 SLM˜20 SLM.

10. The method according to claim 1, wherein the thickness of the tunneling oxide layer is in a range of 30 angstroms˜150 angstroms.

11. A method for manufacturing a flash memory device, the method comprising the following steps:
forming a tunneling oxide layer on a semiconductor substrate by in-situ steam generation oxidation;
performing an annealing on the tunneling oxide layer;
forming a control gate and a floating gate sequentially on the annealed tunneling oxide layer;
forming a source/drain in the semiconductor substrate at both sides of the gate; and
performing a wiring process to form a flash memory device.

12. The method according to claim 11, wherein the step of forming a control gate and a floating gate further comprises:
forming a first conductive layer, an inter-gate dielectric layer, a second conductive layer and a top cover layer sequentially on the tunneling oxide layer;
forming a patterned photoresist layer on the top cover layer to define a gate;
etching the top cover layer, the second conductive layer, the inter-gate dielectric layer, the first conductive layer and the tunneling oxide layer by using the photoresist layer as a mask to form a control gate and a floating gate.

13. A method for manufacturing a tunneling oxide layer, the method comprising the following steps:
forming a tunneling oxide layer on a semiconductor substrate by in-situ steam generation oxidation;
forming a control gate and a floating gate sequentially on the tunneling oxide layer; and
performing an annealing on the tunneling oxide layer.

14. The method according to claim 13, further comprising performing the in-situ steam generation oxidation at a pressure in a range of 3 Torr˜15 Torr and a temperature in a range of 900° C˜1100° C. for 10 seconds˜100 seconds.

15. The method according to claim 14, wherein the gas used in the in-situ steam generation oxidation is H₂ and O₂.

16. The method according to claim 15, wherein the ratio of H₂ to O₂ is 3/10˜1/1.

17. The method according to claim 16, wherein the flow rate of H₂ is 3 SLM˜20 SLM, and the flow rate of O₂ is 3 SLM˜20 SLM.

18. The method according to claim 13, wherein the annealing is a furnace annealing.

19. The method according to claim 18, further comprising performing the annealing at a temperature in a range of 900° C.˜1100° C. for 10 minutes˜200 minutes.

20. The method according to claim 19, wherein the gas used in the annealing is N₂.

21. The method according to claim 20, wherein the flow rate of N₂ is 3 SLM˜20 SLM.

22. The method according to claim 13, wherein the thickness of the tunneling oxide layer is in a range of 30 angstroms˜150 angstroms.

23. The method according to claim 13, wherein the step of forming a control gate and a floating gate further comprises:
forming a first conductive layer, an inter-gate dielectric layer, a second conductive layer and a top cover layer sequentially on the tunneling oxide layer;
forming a patterned photoresist layer on the top cover layer to define a gate;
etching the top cover layer, the second conductive layer, the inter-gate dielectric layer, the first conductive layer and the tunneling oxide layer by using the photoresist layer as a mask to form a control gate and a floating gate.

24. A method for manufacturing a flash memory device, the method comprising the following steps:
forming a tunneling oxide layer on a semiconductor substrate by in-situ steam generation oxidation;
forming a control gate and a floating gate sequentially on the tunneling oxide layer;
performing an annealing on the tunneling oxide layer, after forming the control gate and the floating gate;
forming a source/drain in the semiconductor substrate at both sides of the gate; and
performing a wiring process to form a flash memory device.

25. The method of claim 24, wherein the step of forming a control gate and a floating gate further comprises:
forming a first conductive layer, an inter-gate dielectric layer, a second conductive layer and a top cover layer sequentially on the tunneling oxide layer;
forming a patterned photoresist layer on the top cover layer to define a gate;
etching the top cover layer, the second conductive layer, the inter-gate dielectric layer, the first conductive layer and the tunneling oxide layer by using the photoresist layer as a mask to form a control gate and a floating gate.
